(19) United States
(12) Patent Application Publication
(10) Pub. No.: US 2001/0019760 A1
(43) Pub. Date: Sep. 6, 2001

(54) Direct imaging lithographic printing plate

(76) Inventor: Koichi Kawamura, Shizuoka (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 09/764,128

(22) Filed: Jan. 19, 2001

(30) Foreign Application Priority Data
Jan. 20, 2000 (JP) P.2000-011961
Jan. 20, 2000 (JP) P.2000-011962
May 1, 2000 (JP) P.2000-132282

(51) Int. Cl. G03F 7/06; G03G 13/28; G03C 1/00; B41N 1/00; B41C 1/10; B32B 3/00

(52) U.S. Cl. 428/195; 430/302; 101/473; 430/49; 430/496

(57) ABSTRACT

Provided is a direct imaging lithographic printing plate by having on a support a hydrophilic image-receiving layer comprising a polymer compound that is chemically bonded directly to the support surface and has hydrophilic functional groups. Therein, the hydrophilic functional groups preferably have capabilities of forming chelates together with polyvalent metal ions. The polymer compound may be chemically bonded directly to the support surface at its molecular chain end or may be chemically bonded to a polymer backbone chemically bonded to the support surface at its molecular chain end.

### FIELD OF THE INVENTION

The present invention relates to a direct imaging lithographic printing plate and, more particularly, to a direct imaging lithographic printing plate on which images can be formed directly in a simple way to make a lithographic printing plate (press plate) capable of ensuring a great many sheets of printed matter having clear images and no scumming.

### BACKGROUND OF THE INVENTION

In recent years there have been immense progress in office machines and great development in office automation. Under these circumstances, in the field of graphic arts, expectations have been placed on an offset lithographic printing method. In such a method, images are formed on a direct imaging lithographic printing plate by the use of any of printers, such as an electrophotographic printer, a heat-sensitive transfer printer and an ink-jet printer, and thereby platemaking is effected directly without no other particular processing for making a press plate.

Hitherto known direct imaging lithographic printing plates are each constituted of a support such as paper, a backing layer provided on both sides of the support, and an image-receiving layer as a surface layer provided via an intermediate layer on the backing layer. The backing layer or the intermediate layer comprises a pigment and a water-soluble resin, such as PVA or starch, or a water-dispersible resin such as synthetic resin emulsions. The image-receiving layer generally comprises an inorganic pigment, a water-soluble resin and a waterproofing agent.

However, the press plates made from those direct imaging lithographic printing plates have a problem that increasing an amount of waterproofing agent added or enhancing hydrophobicity by the use of a hydrophobic resin prolongs their press lives but lowers their hydrophilic properties to result in development of scumming, while improving their hydrophilic properties causes deterioration of waterproof properties to shorten their press lives.

In a particular environment of the use under a temperature of 30° C. or higher, those press plates further have a drawback that their surface layers dissolve in a fountain solution used in offset printing, thereby shortening their press lives and causing development of scumming. Moreover, as the foregoing direct imaging lithographic printing plates have image areas drawn with oil-based ink on their image-receiving layers, they have a problem to which no satisfactory solution has been found yet. The problem consists in that, if the oil-based ink has poor adhesion to the image-receiving layer, it comes off the image areas during the printing operation even when the non-image areas have sufficient affinity for water to develop no scumming; as a result, there occurs a shortening of press life.

In addition, direct imaging printing plates having as their image-receiving layers hydrophilic layers comprising titanium dioxide, polyvinyl alcohol and hydrolysis products of tetramethoxysilane (or tetraalkoxysilane) have been proposed (by, e.g., JP-A-3-42679 and JP-A-10-268583: the term “JP-A” as used herein means an “unexamined published Japanese patent application). However, when those plates are made into press plates and actually subjected to printing operations, the images formed thereon are found to have insufficient impression capacity.

### SUMMARY OF THE INVENTION

The invention aims to solve the aforementioned problems of the hitherto known direct imaging lithographic printing plates.

Therefore, an object of the invention is to provide a direct imaging lithographic printing plate which can ensure remarkably improved scumming resistance in an offset plate made therefrom and prevent the offset plate from not only developing uniform scumming throughout but also being dotted with scumming spots.

Another object of the invention is to provide a direct imaging lithographic printing plate from which can be made a press plate capable of producing a great many sheets of printed matter having clear images free of defects and distortion.

As a result of our intensive studies made for attaining the aforementioned objects, it has been found that the foregoing problems can be solved by the use of an image-receiving layer characterized by using a hydrophilic graft polymer that is chemically bonded directly to the support surface, and preferably said hydrophilic graft polymer having hydrophilic functional groups capable of forming chelates together with metal ions, thereby achieving the invention.

More specifically, the invention comprises the following Embodiments (1) to (3):

(1) A direct imaging lithographic printing plate comprising a support and an image-receiving layer provided thereon, said image-receiving layer having hydrophilicity and comprising a polymer compound that is chemically bonded directly to the support surface and has hydrophilic functional groups.

(2) The direct imaging lithographic printing plate according to Embodiment (1), wherein the polymer compound in the image-receiving layer is a polymer compound having hydrophilic functional groups capable of forming chelates together with metal ions.

(3) The direct imaging lithographic printing plate according to Embodiment (1), wherein the polymer compound in the image-receiving layer is a hydrophilic functional group-containing straight-chain polymer compound that is chemically bonded directly to the support surface at its molecular end or a polymer compound constituted of a polymer backbone chemically bonded to the support surface and hydrophilic functional group-containing straight-chain polymer compounds attached to the polymer backbone at the individual molecular chain ends.

Further, it is already known that the hydrophilicity of an image-receiving layer can be enhanced by increasing the hydrophilicity in the image-receiving layer. However, the hitherto known image-receiving layers have a problem that, when it is tried to increase the hydrophilicity therein, they always come to have an increased degree of swelling and become weak in structure to result in lowering of their film strength or deterioration of adhesion to supports.

When the form of surface hydrophilic graft polymer that characterizes the invention is adopted as the image-receiving layer comprising a hydrophilic functional group-containing polymer compound chemically bonded directly to the support surface, the polymer chain has a restraint-free structure, except that it is bound to the support surface, so that water is easy to get into the image-receiving layer. Therefore, the present image-receiving layer is characterized by its great water-receptivity. Indeed, it is reported in literature that the surface hydrophilic graft polymers absorb much water and swell to a great extent. On the other hand, as the surface hydrophilic graft polymer is chemically bonded to the support surface directly, no deterioration of the adhesiveness to the support surface is caused even when the swelling occurs. Thus, although the relation between the water receptivity and the adhesion to the support surface was a tradeoff to the hitherto known arts, the invention can resolve this tradeoff and thereby the present effects is thought to be achieved.

On the aforementioned direct imaging lithographic printing plate, images are directly formed using any of various means, including oil-based ink, an electrophotographic printer, a thermal transfer printer and an ink-jet printer. As a result, the image-formed areas come to have ink-receptivity, while the non-image areas at the image-receiving layer surface are left as they have no ink-receptivity. The image-receiving layer on which images are thus formed constitutes directly a press plate for lithographic printing.

Moreover, it is advantageous for the present direct imaging lithographic printing plate to be provided with an image-receiving layer containing a hydrophilic graft polymer having hydrophilic functional groups capable of forming chelates together with metal ions as the polymer compound having hydrophilic functional groups. In this case, a composition containing polyvalent metal ions is supplied imagewise to the image-receiving layer surface by means of, e.g., an ink-jet printer, and thereby the hydrophilic graft polymer and the metal ions are combined to form chelates. The chelate-formed areas are hardened to form an imagewise pattern of the hydrophobic polymer. In this way, a press plate for lithographic printing is made. The polymer and the metal ions form firm coordination bonds in the areas rendered hydrophobic, so that the hydrophobic polymer image areas have greater strength and higher impression capacity than the image areas of hitherto known ink-jet press plates having hot-sealed hydrophobic particles on the hydrophilic surface.

In addition, the image-receiving layer of the present direct imaging lithographic printing plate uses a hydrophilic polymer attached directly to the support surface by chemical bonding; as a result, the non-image areas have a high level of affinity for water to ensure scumming-free printed matter.

As mentioned above, images are formed directly on the present direct imaging lithographic printing plate by means of oil-based ink, an electrophotographic printer, a thermal transfer printer, an ordinary ink-jet printer or an ink-jet printer using ink containing metal ions, and thereby can be made a press plate for lithographic printing the surface of which is constituted of the image areas as ink-receptive region and the non-image areas having no ink-receptivity.

Therefore, the present direct imaging lithographic printing plate can be mounted in a printing machine immediately after the image formation on the image-receiving layer and subjected to printing operations.

And the present invention can provide a lithographic printing plate for offset printing which has excellent impression capacity. Specifically, the printing plate obtained does not develop uniform scumming throughout but also isn't dotted with scumming spots, and can produce a great many sheets of printed matter having clear images free of defects and distortion.

Further, to the present direct imaging lithographic printing plate, it is advantageous that the support surface (solid surface), directly to which a polymer compound is chemically bonded, be roughened. Roughening the solid surface, as described hereinafter, can bring benefits such that the hydrophilicity in the non-image areas becomes high, and thereby the degree of discrimination between hydrophobic areas and hydrophilic areas is heightened to lead to the securing of high scumming resistance during the printing.

### BRIEF DESCRIPTION OF DRAWINGS

FIG. 1 is a structural diagram schematically showing an example of an apparatus usable for image formation on a direct imaging lithographic printing plate according to the invention.

FIG. 2 is a schematic structural diagram showing the key part of an ink-jet recording device usable for image formation on a direct imaging lithographic printing plate according to the invention.

FIG. 3 is a partial cross-section diagram showing the head of an ink-jet recording device usable for image formation on a direct imaging lithographic printing plate according to the invention.

FIG. 4 is a schematic diagram showing the main part of a head installed in an ink-jet recording device as another usable example for image formation on a direct imaging lithographic printing plate according to the invention.

FIG. 5 is a schematic diagram illustrating the head of the ink-jet recording apparatus shown in FIG. 4.

### DETAILED DESCRIPTION OF THE INVENTION

Modes for carrying out the invention are described below in detail.

[Description of Image-receiving Layer (Hydrophilic Layer) of Direct imaging Lithographic Printing Plate]

The image-receiving layer (also referred to as a surface grafted layer) comprising a polymer compound chemically bonded directly to a support surface and having hydrophilic functional groups, which is characteristic of the present direct imaging lithographic printing plate, has no particular restrictions as to the structure. However, the following two structures can be instanced. One structure is built up of polymer chains having hydrophilic functional groups, preferably hydrophilic functional groups capable of forming chelates together with metal ions, and being chemically bonded directly to a support surface at their respective ends. The other structure is made up of a polymer backbone chemically bonded to a support surface and straight-chain polymer compounds attached to the polymer backbone at their respective chain ends.

The image-receiving layers having the specific structures mentioned above can be formed using various means. As an example, the means referred to as surface graft polymerization can be employed.

(Description of Surface Graft Polymerization)

Graft polymerization is a method of synthesizing a graft polymer by producing active species on a polymer chain and utilizing these active species for initiating polymerization of some other monomer. In a case where the polymer compound providing active species forms a solid surface, the foregoing method is specially referred to as surface graft polymerization.

For the surface graft polymerization enabling the invention to materialize, any of the methods described in literature can be employed. For instance, the photo graft polymerization method and the plasma irradiation graft polymerization method are described as surface graft polymerization methods in Shin Kobunshi Jikkengaku 10 (which means “New Experimental Science of Polymers, volume 10”) , page 135, compiled by Kobunshi Gakkai, published by Kyoritsu Shuppan Co., in 1994. Further, the methods of effecting graft polymerization by exposure to radiation, such as γ-rays and electron beams, are described in Kyuchaku Gijutu Binran (which means “Handbook of Adsorption Technology”), pages 203 and 695, compiled under the supervision of Mr. Takeuchi, published by NTS Co., February 1999.

As specific methods for photo graft polymerization, the methods disclosed in JP-A-10-296895 and JP-A-11-119413 can be adopted.

The other means usable for forming the surface with which a polymer compound directly forms a chemical bond at its molecular chain end, which is characteristic of the present direct imaging lithographic printing plate, consists in that a reactive functional group, such as a trialkoxysilyl group, an isocyanate group, an amino group, a hydroxyl group or a carboxyl group, is introduced to the chain end of a polymer compound and the introduced functional group undergoes coupling reaction with a functional group present at the support surface of the direct imaging lithographic printing plate, thereby forming a chemical bond between the polymer compound and the support surface.

Additionally, the term “support surface” relating to the present direct imaging lithographic printing plate signifies the surface to which the end of a polymer compound is chemically bonded directly or via a polymer backbone. More specifically, such a surface may be either the support surface itself the present direct imaging lithographic printing plate precursor has or the surface of a layer specially provided on the support.

On the other hand, a means for forming the hydrophilic image-receiving layer (the layer grafted on the surface), which is constituted of a polymer backbone chemically bonded to the support surface and straight-chain polymer compounds attached to the polymer backbone at the individual molecular chain ends, comprises synthesizing a grafted polymer compound from a polymer backbone having in side chains functional groups capable of coupling with functional groups present at the support surface and a hydrophilic functional group-containing polymer compound for forming graft chains, and making the synthesized polymer compound undergo coupling reaction with the functional groups present at the support surface.

(Description of Hydrophilic Functional Groups)

Examples of hydrophilic functional groups include a carboxylic acid group, a sulfonic acid group, a sulfinic acid group, a phosphonic acid group, an amino group or a salt thereof, an amido group, a hydroxyl group, an ether linkage, a polyoxyethylene group, and an active methylene group having an acidic hydrogen atom bonded to the carbon adjacent to an electron attracting group, such as acetylacetonate, and a salt thereof.

As examples of hydrophilic functional groups which are employed to advantage because of their ability to form a chelate together with a metal ion, mention may be made of a carboxylic acid group, a sulfonic acid group, an amino group, a hydroxyl group, and an active methylene group and a salt thereof.

[Specific Method of forming Image-receiving Layer comprising Hydrophilic Polymer produced by Surface Graft Polymerization]

The hydrophilic polymer grafted on a support surface can be produced using plasma irradiation graft polymerization or radiant energy irradiation graft polymerization as described in Y. Ikada et al., Macromolecules, vol. 19, page 1804 (1986) in addition to the methods described in the literature cited above. More specifically, a polymer film, such as a PET film, is treated with plasma or electron beams to produce radicals at the film surface, and the thus activated film surface is made to react with a monomer containing a hydrophilic functional group, thereby forming the image-receiving layer.

Examples of a hydrophilic functional group-containing monomer especially useful in the invention include monomers respectively containing a carboxyl group, a sulfonic acid group, a phosphonic acid group, an amino group and salts of these groups, such as (meth) acrylic acid or the alkali metal or amine salts thereof, itaconic acid or the alkali metal or amine salts thereof, 2-hydroxyethyl(meth)acrylate, (meth)acrylamide, N-monomethylol(meth)acrylamide, N-dimethylol(meth)acrylamide, allylamine or the hydrohalogenides thereof, 3-vinylpropionic acid or the alkali metal or amine salts thereof, vinylsulfonic acid or the alkali metal or amine salts thereof, vinylstyrenesulfonic acid or the alkali metal or amine salts thereof, 2-sulfoethylene (meth)acrylate and 3-sulfopropylene (meth)acrylate or the alkali metal or amine salts thereof, polyoxyethylene glycol mono(meth)acrylate, 2-acrylamido-2-methylopropanesulfonic acid or the alkali metal or amine salts, acid phosphoxypolyoxyethylene glycol mono(meth)acrylate, and allylamine or the hydrohalogenides thereof.

[Description of Structure of Direct imaging Lithographic Printing Plate]

The present direct imaging lithographic printing plate has a structure built up of a support and an image-receiving layer comprising a polymer compound that is chemically bonded directly to the support surface and has hydrophilic functional groups. Any support surface may be the support surface of the present direct imaging lithographic printing plate so far as it has functional groups capable of chemically binding to the end of a polymer compound having hydrophilic functional groups, preferably hydrophilic functional groups capable of forming chelates together with metal ions, directly or via a polymer backbone, or it can produce radicals or active species, such as peroxides, when subjected to treatment, such as irradiation with plasma, electron beams, ultraviolet rays or visible light. Specifically, the support surface in the present direct imaging lithographic printing plate may be the surface of the support itself or a layer specially provided on the support.

(Description of Support Surface)

The term “support surface” signifies a surface suitable for grafting thereon the present polymer compound containing hydrophilic functional groups, preferably hydrophilic functional groups capable of forming chelates together with metal ions, (hydrophilic polymer), and the surface may be in any state as far as it develops such a function. Specifically, the support surface may be either inorganic or organic, and the polarity thereof may be either hydrophilic or hydrophobic. Further, the support surface may form a part of the support. In this case, the support surface and the support are integrated into one body. Also, the function required for the present support surface can be attained by surface treatment of a support. Herein, the surface-treated support can be used as a support containing the support surface.

Additionally, it is advantageous that the aforementioned support surface be roughened, to which the polymer compound in the image-receiving layer of the present direct imaging lithographic printing plate is directly bonded.

When the present hydrophilic polymers are synthesized using a method of photo graft polymerization, plasma irradiation graft polymerization or radiant energy irradiation graft polymerization, the support used therein prefers having an organic surface to having an inorganic surface. In particular, the support surface made of an organic polymer is advantageous over others. Examples of an organic polymer usable therefor include synthetic resins, such as epoxy resin, acrylic resin, urethane resin, phenol resin, styrene resin, vinyl resin, polyester resin, polyamide resin, melamine resin and formaldehyde resin, and natural resins such as gelatin, casein, cellulose and starch. In the cases of photo graft polymerization, plasma irradiation graft polymerization and radiant energy irradiation graft polymerization, the graft polymerization is triggered off by drawing hydrogen atoms out of an organic polymer, so that it is favorable from the viewpoint of production suitability to use a polymer from which hydrogen atoms are easily taken away, such as acrylic resin, urethane resin, styrene resin, vinyl resin, polyester resin, polyamide resin or epoxy resin.

Of these resins, acrylic resin, urethane resin, styrene resin, polyester resin, polyamide resin and epoxy resin are preferred from a viewpoint that it can serve as both support and support surface.

Another characteristic of the present direct imaging lithographic printing plate is in that the support surface to be chemically combined with a polymer compound constituting the image-receiving layer is preferably roughened.

Then, the roughness of the support surface (solid surface) used in the invention is described.

[Regulations of Surface Roughness]

As to the two-dimensional roughness parameters of the present support surface, the center-line average roughness Rₐ is from 0.1 to 1 μm, the maximum height R_{y} is from 1 to 10 μm, the ten-point average roughness R_{z} is from 1 to 10 μm, the average space between concave and convex points Sₘ is from 5 to 80 μm, the average space between local peaks S is from 5 to 80 μm, the maximum height Rt is from 1 to 10 μm, the center-line peak height Rₚ is from 1 to 10 μm, and the center-line valley depth Rᵥ is from 1 to 10 μm.

These two-dimensional roughness parameters are based on the following definitions.

Center-line average roughness Rₐ: A value determined by drawing out a portion equal to the measured length L from a roughness curve in the direction of the center line, and taking the arithmetic mean of the absolute values of deviations between the center line of the drawn-out portion and the roughness curve.

Maximum height R_{y}: A value determined by drawing out a reference length portion from a roughness curve in the direction of the average line, and measuring the space between the peak line and the valley bottom line in the direction of vertical magnification of the roughness curve.

Ten-point average roughness R_{z}: A value determined by drawing out a reference length portion from a roughness curve in the direction of the average line, calculating the average of absolute values of from the highest peak height to the fifth highest peak height (Yₚ) and the average of absolute values of from the deepest valley bottom depth to the fifth deepest valley bottom depth (Yᵥ) measured from the drawn-out average line portion in the direction of vertical magnification, and adding these two average values which are expressed in micrometer (μm).

Average space between concave and convex points Sₘ: A value determined by drawing out a reference length portion from a roughness curve in the direction of the average line, finding in the drawn-out portion a length of the average line corresponding to the interval between each of many peaks and a valley adjacent thereto, and taking an arithmetic mean of such intervals expressed in millimeter (mm).

Average space between local peaks S: A value determined by drawing out a reference length portion from a roughness curve in the direction of the average line, finding in the drawn-out portion a length of the average line corresponding to the interval between each pair of adjacent local peaks, and taking an arithmetic mean of such intervals expressed in millimeter (mm).

Maximum height Rₜ: A value determined by drawing out a reference length of portion from a roughness curve, putting the drawn-out portion between two lines parallel to the center line, and measuring the space between these two parallel lines.

Center-line peak height Rₚ: A value determined by drawing out a portion equal to the measured length L from a roughness curve in the direction of the center line, and measuring the space between the center line of the drawn-out portion and the line parallel thereto and touching the highest peak.

Center-line valley depth Rᵥ: A value determined by drawing out a portion equal to the measured length L from a roughness curve in the direction of the center line, and measuring the space between the center line of the drawn-out portion and the line parallel thereto and touching the bottom of the deepest valley.

[Method of Making Rough Surface]

(Types of Making Method)

In order to render a solid surface rough, various means can be adopted. For instance, the solid surface may be scraped mechanically by sandblasting or brushing to form hollows thereon, thereby becoming rough. As another means, mechanical embossing can be adopted for imparting roughness to the solid surface. As still another means, gravure printing may be adopted to form protrusions on the solid surface. As a further means, a layer containing solid fine particles (a matting agent) is formed on the solid surface by coating or printing to render the solid surface rough. The solid fine particles may be incorporated in a polymer film at the stage of film formation (internally added) to form roughness on the polymer film surface. Further, the solid surface can be rendered rough by solvent treatment, corona discharge treatment, plasma treatment, electron beam irradiation or X-ray irradiation. The means as recited above may be used in combination. Of these means, the sandblasting means, the means of forming a rough surface by printing of resin, or the means of forming roughness by the addition of solid fine particles is used to advantage over the other means.

(Means of adding solid fine particles)

As the solid fine particles, various kinds of materials, such as metal fine particles, metal oxide fine particles and organic or inorganic polymer fine particles, can be utilized. Examples of such fine particles include copper powder, tin powder, iron powder, zinc oxide powder, silicon oxide powder, titanium dioxide powder, aluminum oxide powder, molybdenum disulfide powder, calcium carbonate powder, clay, mica, cone starch, boron nitride, silicone resin particles, polystyrene resin particles, fluoropolymeer particles, acrylic resin particles, polyester resin particles, acrylonitrile copolymer resin particles, zinc stearate and calcium behenate. The suitable average size of those fine particles is at least 0.05 μm, preferably at least 0.1 μm. In the case of attaching fine particles to the sheet surface or providing a fine particles-containing layer on the sheet surface, the average size of fine particles is almost equivalent for the roughness of the roughened surface. In the case of incorporating fine particles into a sheet, the roughness depends on the average size of the fine particles and the thickness of the sheet. In the latter case, therefore, it is required for achieving the optimum roughness that the optimum particle size should be determined experimentally depending on the sheet to be combined with the fine particles.

Examples of a method of fixing solid fine particles to the support surface to form roughness include a method of forming a film from a film-forming material to which solid fine particles are added in advance, a method of coating the support surface with a solid fine particles-dispersed binder solution and then drying, a method of pushing fine particles in a film by mechanical pressure after film formation, and a method of electrolytically depositing solid fine particles on a film surface.

The film formation from a film-forming material to which solid fine particles are added in advance can be carried out, e.g., in the following way. The PET master batch in which a pigment as solid fine particles is mixed is melt-extruded, formed into a film on a cooling drum, stretched in the machine direction and then in the cross direction, and finally subjected to heat treatment, thereby preparing a PET film having a rough surface. As the pigment, titanium dioxide, alumina and silica can be used alone or in combination of at least two thereof. The center-line average surface roughness of the film can be adjusted by properly choosing the particle size and the amount of pigment mixed. For instance, the adjustment can be made by mixing a pigment having a particle size of the order of 1-10 μm in a proportion of the order of 0.5-5 weight %, and the center-line average surface roughness becomes greater the larger the particle size and the amount of pigment mixed are. In order to prepare the desired rough surface, it is required to decide the particle size of pigment mixed and to adjust the amount thereof accordingly.

(Sandblasting Method)

The sandblasting is a method of forming roughness on the film surface by high-speed throw of an abrasive having a fine grain size against the polymer film surface. This treatment may be carried out in a conventional manner. For instance, powerful blasts of compressed air with Carborundum (silicon carbide powder) or metal particles are blown against the film surface, washed with water and then dried to achieve the purpose. In the case of sandblasting, the center-line average roughness of the film surface can be adjusted by controlling the particle size of blown particles and the treatment quantity (treatment frequency per area). Therein, the larger the particle size and the treatment quantity, the greater the center-line average roughness of the film surface.

More specifically, the sandblasting treatment is a surface treatment comprising blowing blasts of an abrasive against the film surface by the use of compressed air, and the roughness formed thereby is controlled by choosing conditions under which the sandblasting treatment is carried out.

As to the sandblasting conditions for blowing blasts of an abrasive against the film surface from a sandblast emitting nozzle, it is necessary to properly adjust the quantity of abrasive blown (blast quantity) and the angle and the distance between the sandblast emitting nozzle and the film (blast angle and blast distance). And under the correct conditions the sandblasting treatment is carried out by jetting out an abrasive in a hopper via a sandblast emitting nozzle by means of compressed air sent out from an air chamber and blowing the abrasive against the film surface. To be more specific, the methods for this treatment are described as known methods, e.g., in JP-A-8-34866, JP-A-11-90827 and JP-A-11-254590.

Herein, it is necessary to carry out the sandblasting treatment under a condition that neither abrasive nor abraded matter remains on the film surface after the treatment, and besides, the film strength is retained. Such a condition can be determined empirically.

Specifically, quartz sand and others can be used as abrasive. In particular, quartz sand having a grain size of 0.05 to 10 mm, preferably 0.1 to 1 mm, is used to advantage. And the suitable blast distance is from 100 to 300 mm, the suitable blast angle is from 45 to 90 degrees, preferably from 45 to 60 degrees, and the suitable blast quantity is from 1 to 10 kg/min. This is because these conditions make it possible to leave neither abrasive nor abraded matter on the film surface, e.g., the surface of polyimide film, after sandblasting, and further to properly control the abrasion depth. Additionally, it is desirable that the abrasion depth be kept within the range of 0.01 to 0.1 μm, and thereby the lowering of film strength can be prevented.

(Thickness of Image-receiving Layer)

The present image-receiving layer has a thickness of from 0.01 to 10 g/m², preferably from 0.1 to 5 g/m². When the thickness is decreased below 0.01 g/m², the press life of the resultant plate becomes short; while, when the thickness is increased beyond 10 g/m², the resultant plate cannot ensure satisfactory fine-line reproducibility in the printed matter.

[Methods of Forming Images]

Images are formed on the present direct imaging lithographic printing plate by the use of a thermal-transfer recording method, an electrophotographic recording method or an ink-jet recording method, thereby making a press plate.

One image-forming method which is important and preferable in the invention comprises forming on the hydrophilic image-receiving layer surface an ink-receptive polymer film, as mentioned above, by causing chelation between polymer molecules and metal ions to cross-link the polymer molecules and render them water-insoluble. This method has no particular restriction as to what method is adopted for supplying heavy metal (solution containing metal ions) to the image-receiving layer. In order to demonstrate effects of the invention, however, image formation is carried out using the following two concrete methods and thereby lithographic printing plates (press plates) are made respectively. Needless to say, the invention should not be construed as being limited to these concrete methods alone.

As one of those methods, the method of making a press plate for lithographic printing by the use of an ink-jet recording system is illustrated below. According to this method, the printing on the surface of the present direct imaging lithographic printing plate is done in ink containing metal ions. The image-printed areas of the thus made printing plate are ink-receptive because of their hydrophobicity, while the non-image areas are left hydrophilic. Therefore, this plate can undergo printing operations by being mounted in an offset printer as it is.

Of the ingredients added to the ink used for the ink-jet recording, metal ion alone is an essential component. Other ingredients are not particularly required for the ink, but a variety of water-soluble dyes may be added to the ink for the purpose of making the printed areas visible and easy to see. Also, an alcoholic solvent, such as ethanol, propanol, ethylene glycol or glycerol, may be added for the purpose of preventing a recording head and a nozzle from clogging up.

As examples of metals for metal ions used in the ink, mention may be made of polyvalent metals belonging to the groups II to IV of the periodic table. Of these metals, the group III metals to the group V metals are preferred over the others. In particular, Al, Si and Mg of the group III metals, Ca, Ti, Mn, Fe, Ni, Cu, Zn and Ge of the group IV metals, and Zr, In and Sn of the group V metals are employed to advantage.

Examples of salts of polyvalent metal ions include salts (including complex salts) of two or higher valent cations of metals, such as magnesium, calcium, strontium, barium, aluminum, chromium, manganese, iron, cobalt, nickel, copper, zinc and tin (preferably alkaline earth metals). Any anions may be the counter anions for these cations, but it is preferable to select anions which can form metal salts having good solubility. More specifically, magnesium chloride, magnesium sulfate, magnesium nitrate, magnesium acetate, calcium chloride, calcium sulfate, calcium nitrate and calcium acetate are suitable as the salts of polyvalent metal ions. The appropriate concentration of a polyvalent metal ion salt in the solution is from 0.03 to 5 mole/liter, preferably from 0.1 to 2 mole/liter.

For preventing a recording head from being corroded by those metal ions, it is especially desirable to use a non-corrosive material, such as glass, as material for the recording head.

When an ink-jet recording system is utilized for making a lithographic printing plate, the lithographic printing plate can be made very simply by the use of an existing ink-jet printer. In addition, this platemaking method does not require after-treatment for, e.g., removal of uncured polymer molecules in non-image areas by washing with water, so the lithographic printing plate thus made can be used directly as a press plate. Thus, the ink-jet recording system is especially convenient for the platemaking in the invention.

The resolution of the printing plate made by the foregoing method is dependent on the diameter of a nozzle attached to the head part from which ink is jetted. In other words, it is influenced by the precision of a printer used. When an ink-jet printer with high resolution is not used, therefore, the printing plate obtained has a drawback of being rather inferior in resolution. Thus, the precision of the ink-jet printer used in the platemaking according to the ink-jet recording method is chosen depending on the intended use of the printing plate to be made. Specifically, ordinary ink-jet printers are chosen in the case of simple printing, while high-definition lithographic printing plates can be obtained by the use of high-resolution printers.

The ink-jet recording method used in the invention may be any of hitherto known recording methods. The ink used therein may be either water-based or oil-based ink as far as the metal ions as recited above are added to the ink composition. However, oil-based ink is preferable to water-based ink because the images recorded in oil-based ink can be dried and fixed with ease, and besides, oil-based ink has a small potential for clogging nozzles. Further, the ink-jet recording method of electrostatic jet type is advantageous because the images recorded thereby are almost free of bleeding. In addition, the solid jet recording method using hot melt ink can also be used to advantage.

For the ink-jet recording of electrostatic jet type, the recording apparatus as disclosed in World Patents WO93/11866, WO97/27058 or WO97/27060 can be employed. The oil-based ink suitably used therein is a dispersion prepared by dispersing hydrophobic resin particles, which are in a solid state at least under ordinary temperature (15° C. to 35° C.) , into a non-aqueous solvent (as a dispersion medium) having an electric resistance of at least 10⁹Ω·cm and a permittivity of at most 3.5. By the use of such a dispersion medium, the electric resistance of the oil-based ink can be controlled properly to enable appropriate jet of ink by electric field, thereby resulting in improvement of image quality. Further, the incorporation of such resin particles in the oil-based ink can increase an affinity for the image-receiving layer to result in recording of good-quality images and enhanced impression capacity.

Examples of oil-based ink suitably used in the invention include those disclosed in JP-A-10-259336, Japanese Patent Application No. 9-154509, JP-A-10-316920, JP-A-10-204354, JP-A-10-204356 and JP-A-10-315617.

For the solid jet recording method, commercially available printing systems, such as Solid Ink-jet Platemaker SJ02A (made by Hitachi Koki Co., Ltd.), can be employed.

The platemaking methods utilizing an ink-jet recording method are illustrated concretely by the use of drawings.

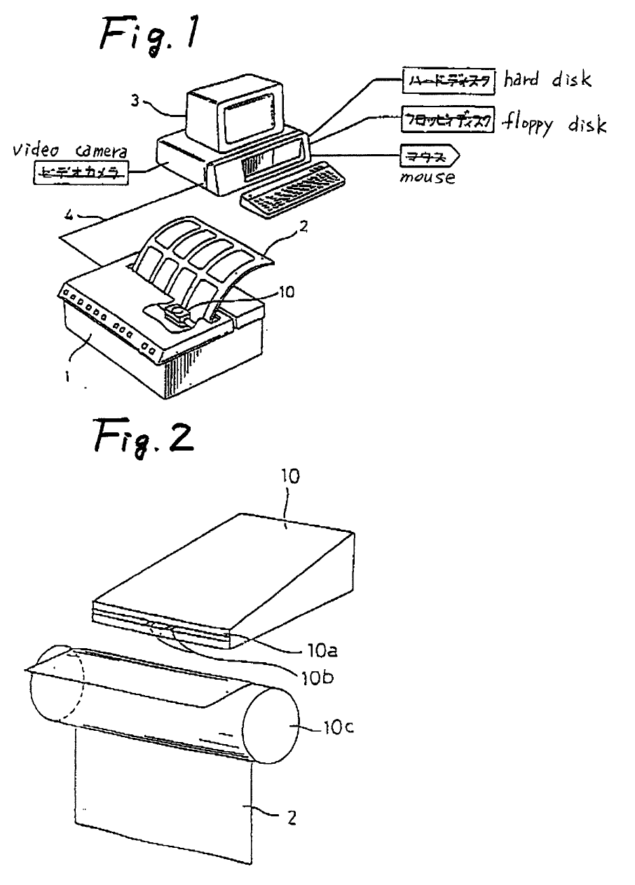

The platemaking system shown in FIG. 1 has an ink-jet recording apparatus 1 using oil-based ink.

As shown in FIG. 1, pattern information about images to be formed on a master 2 (direct imaging lithographic printing plate) is fed from a computer 3 as an information supplying source into an ink-jet recording apparatus 1 via a bus 4 as a information conveying means. The recording apparatus 1 is equipped with a ink-jet recording head 10, and the recording head 10 has a store of oil-based ink on the inside thereof. When the master 2 is passed through the recording apparatus 1, fine droplets of the ink are blown against the master 2 depending on the pattern information, and thereby the ink adheres to the master 2 in the pattern of images.

In the aforementioned manner, the images are formed on the master 2 to result in preparation of a processed master (lithographic printing plate).

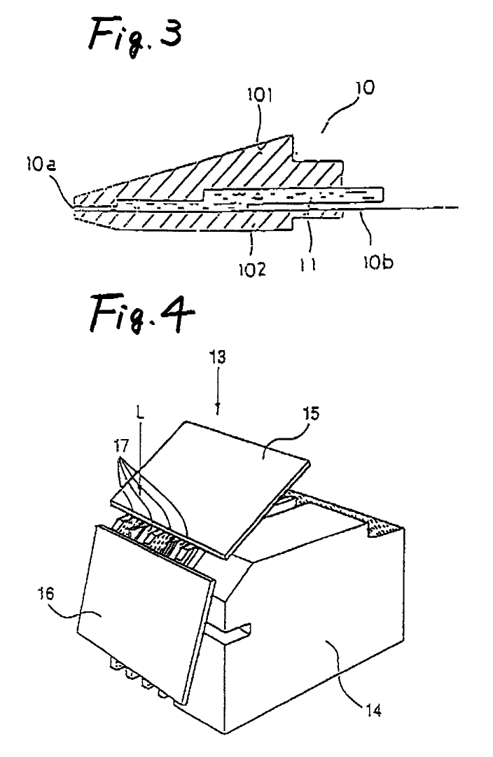

An example of an ink-jet recording apparatus used in the platemaking system shown in FIG. 1 is illustrated in FIG. 2 and FIG. 3. In FIGS. 2 and 3, the members drawn FIG. 1 also are represented by their respective common reference numerals.

FIG. 2 is a schematic structural view showing the necessary parts of such an ink-jet recording apparatus, and FIG. 3 is a cross-sectional view showing a part of the ink-jet recording head.

The head 10 installed in the ink-jet recording apparatus, as shown in FIG. 3, has a slit interposed between the upper unit 101 and lower unit 102, and the tip thereof forms an ink-jet slit 10a. In the slit is disposed an ink-jet electrode 10b, and the slit is filled with oil-based ink 11.

To the ink-jet electrode 10b in the head 10 are applied voltages according to digital signals based on the pattern information about images. As shown in FIG. 2, the ink-jet electrode 10b is arranged facing to a counter electrode 10c, and the master 2 is mounted on the counter electrode 10c. By voltage application, a circuit is formed between the ink-jet electrode 10b and the counter electrode 10c, and thereby the oil-based ink 11 is jetted out from the ink-jet slit 10a of the head 10. In this way, images are formed on the master 2 mounted on the counter electrode 10c.

From the viewpoint of high-quality image formation, it is favorable that the tip of the ink-jet electrode 10b be made as narrower as possible.

For instance, images made up of dots having a diameter of 40 μm can be formed on the master 2 under conditions that the head 10 shown in FIG. 3 is filled with oil-based ink, the ink-jet electrode 10b having a tip width of 20 μm is used, the space between the ink-jet electrode 10b and the counter electrode 10c is adjusted to 1.5 mm and the voltage of 3 KV is applied for 0.1 millisecond between these electrodes.

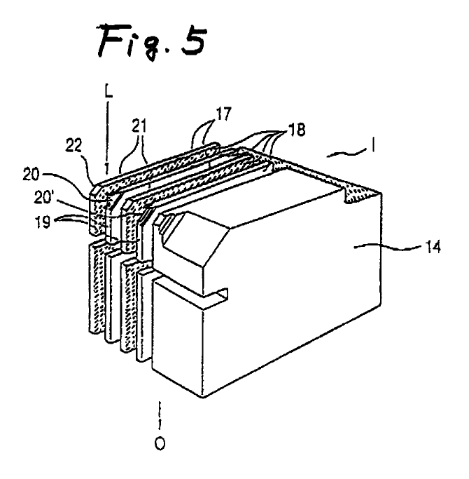

Another structural example of an ink-jet recording apparatus is shown in FIG. 4 and FIG. 5.

FIG. 4 is a schematic view illustrating only a part of the head. The ink-jet recording head 13, as shown in FIG. 4, comprises a head body 14 made of an insulating material, such as plastics, ceramics or glass, and meniscus regulation boards 15 and 16. The reference numeral 17 in the figures stands for ink-jet electrodes to which a voltage is applied to form an electrostatic field in the ink jetting-out part.

Further, the head body is illustrated in detail by reference to FIG. 5 wherein the regulation boards 15 and 16 are removed from the head. The head body 14 has a plurality of ink grooves 18 cut perpendicularly to the edge thereof for the purpose of ink circulation. The grooves 18 each may have any shape as far as it can provide a capillary attraction enough to form a uniform ink flow. However, it is especially advantageous that the width of each groove be from 10 to 200 μm and the depth thereof be from 10 to 300 μm. The ink-jet electrodes 17 are provided in the grooves 18 respectively. On the head body 14 made of an insulating material, these ink-jet electrodes 17 are formed by using a conductive material, such as aluminum, nickel, chromium, gold or platinum, according to the known method in a state that each of them is arranged so as to cover the whole surface of their respective grooves or formed on only a part of each groove. Additionally, the ink-jet electrodes are electrically isolated from one another.

Each pair of two ink grooves adjacent to each other form one cell, and the partition 19 in the center of the cell has an ink jetting-out part 20 or 20′ in the tip part. The partition 19 is made thinner in the ink jetting-out part 20 or 20′ than the other part thereof, and each ink jetting-out part is sharpened. Additionally, the ink jetting-out part tip may be beveled like 20′. The head body having the shape as mentioned above is made using a conventional method, such as mechanical processing or etching of an insulating material block, or molding of an insulating material. In the ink jetting-out part, it is desirable for the partition to have a thickness of from 5 to 100 μm and for the sharpened tip of the partition to have a curvature radius of from 5 to 50 μm. Making additional remark, only two cells are depicted in the figure for convenience's sake. Between the two cells, a partition 21 is disposed, and the tip part thereof 22 is cut off so as to stand back, compared with the ink jetting-out parts 20 and 20′.

The ink is flowed into the head via ink grooves from the direction of I by the use of an ink supply device, which is not shown in the figure, and thereby supplied to the ink jetting-out parts. Further, the excess ink is recovered in the direction O with an ink recovering means, which is not shown in the figure, too. As a result, fresh ink is always supplied to each ink jetting-out part. While exposing the ink in the vicinity of the ink jetting-out part to light like L, the signal voltages according to the image information are applied between each ink-jet electrode and the counter electrode holding a direct imaging lithographic printing plate on the surface, which is not shown in the figure but arranged so as to face on the ink jetting-out part. By the voltages applied, the ink is jetted out from the ink jetting-out part to form the images on the direct imaging lithographic printing plate.

As mentioned above, images can be formed on a direct imaging printing plate in accordance with an ink-jet recording method using oil-based ink. Thus, the processed master (lithographic printing plate) can be obtained.

As another example of a platemaking method usable in the invention, mention may be made of a method of utilizing a silver complex salt diffusion transfer process for the supply of metal ions. In carrying out this method, a doner sheet coated with a silver salt photosensitive material is prepared in addition to a direct imaging lithographic printing plate according to the invention. After imagewise exposure, the doner sheet is subjected to development in the presence of a complexing material capable of dissolving silver halide in the unexposed areas. Therein, the exposed areas of the silver salt photosensitive material undergoes chemical development, while the silver halide in the unexposed areas forms a complex together with such a solvent and thereby dissolves (the phenomena caused in exposed and unexposed areas respectively are reversed in a direct-positive photosensitive material). At the time of development, the doner sheet is brought into face-to-face contact with the direct imaging lithographic printing plate, and thereby silver ions can be transferred from the silver salt photosensitive material onto the image-receiving layer of the direct imaging lithographic printing plate. Simultaneously with the transfer of silver complex ion, the polymer compound constituting the image-receiving layer is cured since it has hydrophilic functional groups capable of forming chelates together with metal ions. Thus, the hardened film is formed in the silver complex ion-transferred areas alone.

With respect to the foregoing electrophotographic recording method, any of hitherto known recording methods can be adopted for platemaking in the invention. Specifically, the methods described in Denshishashin Gijutsu no Kiso to Oyo (which means “Fundamentals and Applications of Electrophotographic Technology”), compiled by Denshishashin Gakkai, published by Corona Co., Ltd. in 1988, Ken-ichi Eda, Denshishashin Gakkai-shi (which means “Journal of Electrophotographic Society”), 27, 113 (1988), and Akio Kawamoto, Denshishashin Gakkai-shi, 33, 149 (1944) and ibid. , 32, 196 (1993), or commercially available PPC copiers can be employed.

The combination of a scanning exposure method using laser beams emitted on the basis of digital information and a developing method using a liquid developer enables formation of highly precise images, so it constitutes an effective process. Such an electrophotographic recording process is illustrated below by an example.

First an electrophotographic photoreceptor is placed on a flat bed and registered with register pins. Further, the photoreceptor undergoes air suction on the back, and thereby it is fixed to the bed. Then, the photoreceptor is charged with a charging device as described, e.g., in the book cited above, Denshishashin Gijutsuno Kiso to Oyo, from page 212 onward. As a charging device, a corotron or a scorotron is generally used. In the charging operation, it is also beneficial to control the charging condition so as to maintain the surface potential within the intended range by applying feedback based on the information from a means of detecting a potential of the photoreceptor charged. Next, the charged photoreceptor is subjected to scanning exposure with laser beams according to the method described, e.g., in the foregoing reference book, from page 254 onward.

Thereafter, toner image formation is carried out using a liquid developer. The electrophotographic photoreceptor which has been charged and exposed on the flat bed is removed from the flat bed, and can be subjected to wet development shown in the foregoing reference book, from page 275 onward. In this process, the exposure mode is chosen depending on the development mode of toner image. For instance, in the case of reversal development, the negative image mode, or the mode of irradiating image areas with laser beams, is chosen, and the toner having a charge of the same polarity as that of the charged photoreceptor is used. By doing so, the toner is electrodeposited on the exposed areas under a development bias voltage applied thereto. For details of the principle of such a toner image formation, the foregoing reference book, from page 157 onward, can be referred to.

After development, as described in the above reference on page 283, the excess developer is removed by a squeegee operation with a rubber roller, a gap roller or a reverse roller, or by corona squeegee or air squeegee. Prior to such a squeegeeing operation, the plate may be rinsed with a carrier liquid of the developer.

Then, the toner images formed on the photoreceptor are transferred and fixed to a direct imaging lithographic printing plate directly or via an intermediate transfer material, thereby making a lithographic printing plate.

(Support)

The support used in the invention, though has no particular restriction, is a dimensionally stable sheet material. Examples of such a material include paper, paper laminated with plastic (e.g., polyethylene terephthalate, polyethylene, polypropylene, polystyrene), a metal sheet (e.g., an aluminum, zinc or copper sheet) ,a plastic film (e.g., cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate or polyvinyl acetal film), and paper or plastic film on which the metal as recited above is laminated or evaporated.

Of these materials, polyester film or aluminum plate is preferred as the support used in the invention. In particular, polyester film is used to advantage because it can serve as the present support surface also.

Additionally, when the support material used for the present direct imaging lithographic printing plate serves as the support surface also, the support surface conditions described hereinbefore in detail can be applied thereto. For instance, as mentioned above, it is advantageous for the support surface to be roughened.

Now, the invention is illustrated in greater detail by reference to the following examples, but it should be understood that these examples are not to be construed as limiting the scope of the invention in any way.

### EXAMPLE 1

### Image Formation by Ink-jet Method using Oil-based Ink

(Preparation of Direct imaging Lithographic Printing Plate)

A 188 μm-thick biaxially stretched polyethylene terephthalate film (A4100, produced by Toyobo Co., Ltd.) was employed as support, and subjected to oxygen glow treatment using a flat-plate magnetron sputtering apparatus (Model CFS-10-EP70, made by Shibaura Eletec Corporation) under the conditions described below.

(Conditions for Oxygen Glow Treatment)

Initial vacuum: 1.2×10⁻³ Pa

Argon pressure: 0.9 Pa

RF glow; 1.5 KW

Treatment time: 60 sec.

Then, the glow-treated film was immersed in a 60° C. water solution of acrylic acid (20 weight %) for 3 hours as a stream of nitrogen was bubbled through the solution, followed by 10-minute washing with running water. As a result, the acrylic acid was grafted on the film surface in a polymerized form, thereby producing a direct imaging lithographic printing plate having hydrophilicity. The weight of the image-receiving layer thus formed (amount grafted) was measured by gravimetry, and found to be 0.3 g/m²

<Preparation of Oil-based Ink (IK-1)>

(Preparation of Resin Particles)

A solution prepared by mixing 14 g of poly(dodecyl methacrylate), 100 g of vinyl acetate, 4.0 g octadecyl methacrylate and 286 g of Isopar H was heated up to 70° C. with stirring in a stream of nitrogen. Thereto, 1.5 g of 2,2′-azobis (isovaleronitrile) (abbreviatedas “A.I.V.N.”) was added. In the resulting mixture, polymerization reaction was run for 4 hours. Then, the reaction mixture was admixed with 0.8 g of 2,2′-azobis(isobutyronitrile) (abbreviated as “A.I.B.N.”), and heated to 80° C. Further, the reaction was continued for 2 hours. Subsequently thereto, the reaction mixture was admixed with 0.6 g of A.I.B.N., and therein the reaction was continued for 2 hours. Thereafter, the resulting reaction mixture was heated up to 100° C. and stirred for 1 hour as it was, thereby distilling away the monomers left unreacted. After cooling, the reaction product was passed through 200-mesh nylon cloth. The thus obtained white dispersion was a latex having a polymerization rate of 93% and an average particle size of 0.35 μm. The particle size was measured with CAPA-500 (made by Horiba, Ltd.).

(Preparation of Ink)

In a paint shaker (made by Toyo Seiki Seisaku-Sho, Ltd.), 10 g of a copolymer of dodecyl methacrylate and acrylic acid (98/2 by weight), 10 g of Alkali Blue and 30 g of Shellsol 71 were placed together with glass beads, and dispersed for 4 hours. Thus, a blue dispersion containing fine particles of Alkali blue was obtained.

The foregoing resin particles in an amount of 50 g (on a solids basis), 5 g (on a solids basis) of the foregoing blue dispersion and 0.08 g of copolymer of octadecene and maleic acid semioctadecylamide were diluted with 1 liter of Isopar G to prepare oil-based blue ink (IK-1)

A servo plotter DA8400, made by Graphtec Corp., for imaging the output of a personal computer was modified so that the ink jetting-out head was mounted on the pen plotter part as shown in FIG. 2, and the aforementioned direct imaging lithographic printing plate was placed on the counter electrode. Therein, the space between the head and the counter electrode was adjusted to 1.5 mm. The printing with the foregoing oil-based ink (IK-1) was carried out on the direct imaging lithographic printing plate to make a lithographic printing plate. In making the printing plate, the underlayer provided underneath the image-receiving layer of the direct imaging lithographic printing plate and the counter electrode are electrically connected to each other by the use of silver paste.

The printing plate was adjusted so as to have a surface temperature of 70° C. for 10 seconds by means of a Ricoh Fuser (made by Ricoh Company Ltd.), and thereby the ink images printed thereon were fixed.

The drawn images of the thus obtained press plate (lithographic printing plate) were evaluated by observation under an optical microscope of a 200X magnification. As a result, the fine lines and fine letters constituting the drawn images were found to be free of bleeding and defects. In other words, the observation has proved that the images on the press plate were clear images.

Then, the printing on printing paper was performed via the press plate made in the foregoing manner by means of a printing machine, Model Oliver 94 (made by K. K. Sakurai Seisakusho). Therein, a solution of EU-3 (a product of Fuji Photo Film Co. Ltd.) diluted with distilled water so as to have a 1/100 concentration was used as a fountain solution, and placed in the dampening saucer. As to the printing ink, a black ink for offset printing was employed.

The images on the tenth impression were evaluated by visual observation through a 20X loupe. As a result, it was found that the non-image area was free of the scumming arising from adhesion of printing ink and the solid areas were highly uniform. Further, these printed images were observed under an optical microscope of a 200X magnification, and thereby they proved to be free of thinned or missing fine lines and letters, namely high-quality images.

By repetition of the printing operations mentioned above were obtained 4,000 sheets of printed matter equivalent in image quality to the tenth impression.

### EXAMPLES 2 TO 5

### Image Formation by Ink-jet Method using Oil-based Ink

Direct imaging lithographic printing plates were prepared in the same manner as in Example 1, except that the monomers shown in Table 1 were used respectively as the hydrophilic monomer for forming image-receiving layers by the graft polymerization, and thereon were formed images by the same method as in Example 1. The qualities of impressions obtained from the thus made press plate were evaluated in the same way as in Example 1. The evaluation results are also shown in Table 1.

TABLE 1

| | | | Impression |
|---|---|---|---|
| | | Weight of | Quality |
| | | Hydrophilic | (scumming on |
| | Hydrophilic | Layer (amount | 4000th |
| Example | monomer | grafted) | impression) |
| 2 | acrylamide | 1.0 g/m² | no scumming |
| 3 | 2-acrylamide-2- | | |
| | methylpropane-sulfonic | 0.8 g/m² | no scumming |
| | acid | | |
| 4 | sodium | 0.5 g/m² | no scumming |
| | 4-styrene-sulfonate | | |
| 5 | 2-hydroxyethyl | 0.6 g/m² | no scumming |
| | acrylate | | |

Each of the direct imaging lithographic printing plates prepared in Examples 1 to 5 according to the invention provided at least 4,000 sheets of good-quality printed matter which were free of scumming in the non-image areas, namely satisfactory results were obtained in each Example.

### EXAMPLE 6

### Positive-working, Direct imaging Lithographic Printing Plate

(Formation of Image-receiving Layer)

The film having undergone the same glow treatment as in Example 1 was used as a support. And the support was immersed in a 60° C. water solution of acrylic acid (20 weight %) for 4 hours as a stream of nitrogen was bubbled through the solution, followed by 10-minute washing with running water. As a result, the acrylic acid was grafted on the support surface in a polymerized form, thereby producing a direct imaging lithographic printing plate having hydrophilicity.

The weight of the image-receiving layer thus formed (graft weight) was determined by gravimetry, and found to be 1.3 g/m².

On the direct imaging lithographic printing plate thus produced, test patterns were printed by the use of an ink-jet printer, INK-JET Printer Model IO-735 (made by Sharp Corporation), and the ink having the following composition. The thus printed plate was used directly as a press plate without any after-treatments.

(Composition of Ink)

| | | |
|---|---|---|
| Water | 100 | ml |
| Ferric sulfate | 3 | g |
| Acid Blue 9 (C.I. 42090) | 1 | g |
| Ethylene glycol | 10 | g |

Then, the press plate obtained was mounted in the following offset printing machine, and subjected to printing operations, followed by evaluation of its printing characteristics. As a result, it was found that no scumming developed even after the printing was done on 10,000 sheets of printing paper and no problems occurred during the printing operations.

(Printing Method)

The press plate obtained in the foregoing manner was mounted in an offset printer, Ryobi 3200CD, and subjected to printing operations in the atmosphere of a temperature of 22° C. and a humidity of 60%.

Therein, the fountain solution used was a commercially available fountain solution, and the printing ink used was F Gloss Black Ink B produced by Dai-Nippon Ink & Chemicals, Inc.

(Evaluation of Printing Characteristics)

The printing characteristics of the foregoing press plate were judged from visual observation of the extent of scumming on the printed matter obtained, and the impression capacity was evaluated by carrying out printing on 10,000 sheets of printing paper under the same conditions as mentioned above.

### EXAMPLE 7

### Image Formation of Ink-jet Method using Oil-based Ink

[Production of Support 1 plus Hydrophilic Layer]

On the following surface-roughened Support 1, acrylic acid was grafted in the form of polymer by a photo-grafting method, thereby forming a hydrophilic layer. The contact angle of the thus formed hydrophilic layer was found to be 10° (water drop in the air, measured with Model CA-Z, a product of Kyowa Kaimen Kagaku Co., Ltd.).

(Photo Grafting Method)

A photo graft polymerizing solution constituted of 50 g of acrylic acid, 0.03 g of sodium periodate and 200 g of water was placed in a vessel made of Pyrex glass, and therein the PET film described below was immersed. Then, the air inside the vessel was replaced with argon gas, and the glass vessel was exposed to light for 30 minutes by means of a high-pressure mercury lamp of 400 watts, Model UVL-400P (made by Riko Kagaku Sangyo Co., Ltd.), placed at a distance of 10 cm. The film formed by the graft polymerization reaction was washed with 40° C. water for 8 hours.

(Surface-roughened Support 1)

A sand-blasted 188 μm-thick PET film having surface roughness expressed in Ra (center-line average roughness) of 0.7 μm and Ry (maximum height roughness) of 7 μm (a product of Panac Kogyo co., Ltd.).

The weight of the image-receiving layer (amount grafted) in the thus formed direct imaging lithographic printing plate was measured by gravimetry, and found to be 0.3 g/m².

<Preparation of Oil-based Ink (IK-1)>

(Preparation of Resin Particles)

A solution prepared by mixing 14 g of poly(dodecyl methacrylate), 100 g of vinyl acetate, 4.0 g octadecyl methacrylate and 286 g of Isopar H was heated up to 70° C. with stirring in a stream of nitrogen. Thereto, 1.5 g of 2,2′-azobis(isovaleronitrile) (abbreviated as “A.I.V.N.”) was added. In the resulting mixture, polymerization reaction was run for 4 hours. Then, the reaction mixture was admixed with 0.8 g of 2,2′-azobis(isobutyronitrile) (abbreviated as “A.I.B.N.”), and heated to 80° C. Further, the reaction was continued for 2 hours. Subsequently thereto, the reaction mixture was admixed with 0.6 g of A.I.B.N., and therein the reaction was continued for 2 hours. Thereafter, the resulting reaction mixture was heated up to 100° C. and stirred for 1 hour as it was, thereby distilling away the monomers left unreacted. After cooling, the reaction product was passed through 200-mesh nylon cloth. The thus obtained white dispersion was a latex having a polymerization rate of 93% and an average particle size of 0.35 μm. The particle size was measured with CAPA-500 (made by Horiba, Ltd.).

(Preparation of Ink)

In a paint shaker (made by Toyo Seiki Seisaku-Sho, Ltd.), 10 g of a copolymer of dodecyl methacrylate and acrylic acid (98/2 by weight), 10 g of Alkali Blue and 30 g of Shellsol 71 were placed together with glass beads, and dispersed for 4 hours. Thus, a blue dispersion containing fine particles of Alkali blue was obtained.

The foregoing resin particles in an amount of 50 g (on a solids basis), 5 g (on a solids basis) of the foregoing blue dispersion and 0.08 g of copolymer of octadecene and maleic acid semioctadecylamide were diluted with 1 liter of Isopar G to prepare oil-based blue ink (IK-1)

A servo plotter DA8400, made by Graphtec Corp., for imaging the output of a personal computer was modified so that the ink jetting-out head was mounted on the pen plotter part as shown in FIG. 2, and the aforementioned direct imaging lithographic printing plate was placed on the counter electrode. Therein, the space between the head and the counter electrode was adjusted to 1.5 mm. The printing with the foregoing oil-based ink (IK-1) was carried out on the direct imaging lithographic printing plate to make a lithographic printing plate. In making the printing plate, the underlayer provided underneath the image-receiving layer of the direct imaging lithographic printing plate and the counter electrode are electrically connected to each other by the use of silver paste.

The printing plate was adjusted so as to have a surface temperature of 70° C. for 10 seconds by means of a Ricoh Fuser (made by Ricoh Company Ltd.), and thereby the ink images printed thereon were fixed.

The drawn images of the thus obtained press plate (lithographic printing plate) were evaluated by observation under an optical microscope of a 200X magnification. As a result, the fine lines and fine letters constituting the drawn images were found to be free of bleeding and defects. In other words, the observation has proved that the images on the press plate were clear images.

Then, the printing on printing paper was performed via the press plate made in the foregoing manner by means of a printing machine, Model Oliver 94 (made by K. K. Sakurai Seisakusho). Therein, a solution of EU-3 (a product of Fuji Photo Film Co. Ltd.) diluted with distilled water so as to have a 1/100 concentration was used as a fountain solution, and placed in the dampening saucer. As to the printing ink, a black ink for offset printing was employed.

The images on the tenth impression were evaluated by visual observation through a 20X loupe. As a result, it was found that the non-image area was free of the scumming arising from adhesion of printing ink and the solid areas were highly uniform. Further, these printed images were observed under an optical microscope of a 200X magnification, and thereby they proved to be free of thinned or missing fine lines and letters, namely high-quality images.

By repetition of the printing operations mentioned above were obtained 15,000 sheets of printed matter equivalent in image quality to the tenth impression.

### EXAMPLES 8 TO 11

### Positive-working, Direct imaging Lithographic Printing Plate

(Production of Image-forming Layer)

Direct imaging lithographic printing plates (printing plate precursors) were prepared in the same manner as in Example 7 using the surface-roughened Support 1, except that the monomers shown in Table 2 were used respectively as the hydrophilic monomer. Each of the thus prepared plates for direct imaging had an image-receiving layer formed by grafting on the support each hydrophilic monomer capable of forming a chelate together with a metal ion in the form of polymer. The weight of the thus formed image-receiving layers each (graft weight) was determined by gravimetry, and found to be 1.3 g/m².

On each of the direct imaging lithographic printing plates thus produced, test patterns were printed by the use of an ink-jet printer, INK-JET Printer Model IO-735 (made by Sharp Corporation), and the ink having the following composition. The thus printed plates were each used directly as a press plate without any after-treatments.

(Composition of Ink)

| | | |
|---|---|---|
| Water | 100 | ml |
| Ferric sulfate | 3 | g |
| Acid Blue 9 (C.I. 42090) | 1 | g |
| Ethylene glycol | 10 | g |

Then, the press plates obtained were each mounted in the following offset printing machine, and subjected to printing operations, followed by evaluation of their printing characteristics.

(Printing Method)

The press plates obtained in the foregoing manner were each mounted in an offset printer, Ryobi 3200CD, and subjected to printing operations in the atmosphere of a temperature of 22° C. and a humidity of 60%.

Therein, the fountain solution used was a commercially available fountain solution, and the printing ink used was F Gloss Black Ink B produced by Dai-Nippon Ink & Chemicals, Inc.

(Evaluation of Printing Characteristics)

The printing characteristics of the foregoing press plate were judged from visual observation of the extent of scumming on the printed matter obtained, and the impression capacity was evaluated by carrying out printing on 15,000 sheets of printing paper under the same conditions as mentioned above. As a result, it was found that no scumming developed even after the printing was done on 15,000 sheets of printing paper and no problems occurred during the printing operations. Evaluation results are shown in Table 2.

TABLE 2

| | Printing | | | |
|---|---|---|---|---|
| | plate | Hydrophilic | | Printing |
| Example | precursor | monomer | Support | Result |
| 8 | 8 | acrylamide | 1 | no scumming |
| 9 | 9 | 2-acrylamide-2- | 1 | no scumming |
| | | methylpropane- | | |
| | | sulfonic acid | | |
| 10 | 10 | Sodium | 1 | no scumming |
| | | 4-styrene- | | |
| | | sulfonate | | |
| 11 | 11 | 2-hydroxyethyl- | 1 | no scumming |
| | | acrylate | | |

Each of the direct imaging lithographic printing plates prepared in Examples 8 to 11 relating to the invention provided at least 15,000 sheets of good-quality printed matter which were free of scumming in the non-image areas, namely satisfactory results were obtained in each Example.

As described above, the present direct imaging lithographic printing plates were each structured so as to have on a support an image-receiving layer comprising a polymer compound that is chemically bonded directly to the support surface and has hydrophilic functional groups, preferably hydrophilic functional groups capable of forming chelates together with metal ions. Therefore, the image-receiving layer constituting each of the present direct imaging lithographic printing plates can have high water receptivity and great bonding strength to the support.

On each of the present direct imaging lithographic printing plates, images can be directly formed using, e.g., an electrophotographic printer, a thermal transfer printer or an ink-jet printer. Thus, the image-formed areas come to have ink-receptivity and the non-image areas at the image-receiving layer surface remain as they have no ink-receptivity; as a result, the plate face suitable for lithography is formed. The thus obtained lithographic printing plates each can be mounted directly in a printing machine and printing operations can be started immediately.

In the case where the image-receiving layer comprises a polymer compound having hydrophilic functional groups capable of forming chelates together with metal ions, imagewise application of a solution containing polyvalent metal ions to the image-receiving layer surface by the use of an ink-jet printer or the like causes chelate formation between the hydrophilic graft polymer and the metal ions to harden the areas on which the chelates are formed. Thus, a lithographic printing plate having an imagewise pattern of hydrophobic polymer is made.

In the foregoing direct imaging lithographic printing plate, the areas rendered hydrophobic form strong coordination bonds to metal ions. Therefore, the image areas are sturdy, and so they can ensure high impression capacity; while the non-image area has a high level of hydrophilicity, and so it enables the production of printed matter free of scumming. The plate on which images are thus formed can be directly mounted as a press plate in a printing machine, and subjected to printing operations.

While the invention has been described in detail and with reference to specific embodiments thereof, it will be apparent to one skilled in the art that various changes and modifications can be made therein without departing from the spirit and scope thereof.

This application is based on Japanese patent applications No. 2000-011961 filed on Jan. 20, 2000, No. 2000-011962 filed on Jan. 20, 2000 and No. 2000-132282 filed on May 1, 2000, the entire contents of which incorporated herein by reference.

What is claimed is:

1. A direct imaging lithographic printing plate comprising a support and an image-receiving layer provided thereon, said image-receiving layer having hydrophilicity and comprising a polymer compound that is chemically bonded directly to the support surface and has hydrophilic functional groups.

2. The direct imaging lithographic printing plate according to claim 1, wherein the polymer compound in the image-receiving layer is a polymer compound having hydrophilic functional groups capable of forming chelates together with metal ions.

3. The direct imaging lithographic printing plate according to claim 1, wherein the polymer compound in the image-receiving layer is a hydrophilic functional group-containing straight-chain polymer compound that is chemically bonded directly to the support surface at its molecular end or a polymer compound constituted of a polymer backbone chemically bonded to the support surface and hydrophilic functional group-containing straight-chain polymer compounds attached to the polymer backbone at the individual molecular chain ends.

4. The direct imaging lithographic printing plate according to claim 2, wherein the hydrophilic functional group capable of forming chelates together with metal ions is selected from the group consisting of carboxylic acid group, a sulfonic acid group, an amino group, a hydroxyl group, and an active methylene group and a salt thereof.

5. The direct imaging lithographic printing plate according to claim 1, wherein the support surface is subjected to surface roughening.

6. The direct imaging lithographic printing plate according to claim 1, wherein the image-receiving layer has a thickness of from 0.01 to 10 g/m².

7. The direct imaging lithographic printing plate according to claim 1, wherein the image-receiving layer has a thickness of from 0.1 to 5 g/m².
